(19) United States
(12) Patent Application Publication
(10) Pub. No.: US 2025/0048602 A1
(43) Pub. Date: Feb. 6, 2025

(54) REFRIGERATION DEVICE AND DATA CENTER

(71) Applicant: Hebei Qinhuai Data Co., Limited., Zhangjiakou City (CN)

(72) Inventor: Binghua ZHANG, Zhangjiakou City (CN)

(21) Appl. No.: 18/792,305

(22) Filed: Aug. 1, 2024

(30) Foreign Application Priority Data
Aug. 4, 2023 (CN) 202310980109.5

(51) Int. Cl. H05K 7/20; F25B 7/00

(52) U.S. Cl. CPC H05K 7/20827; F25B 7/00; H05K 7/20145; H05K 7/20309; H05K 7/20318; H05K 7/20354

(57) ABSTRACT

The present disclosure discloses a refrigeration device and a data center, where the refrigeration device includes a plurality of evaporators arranged in a first air duct forming an air circuit with an inner cavity of a computer room, and the air circuit is configured for flow of air. The plurality of evaporators are arranged at intervals in an array, and a connecting line between any two of the plurality of evaporators intersects in a direction of flow of the air in the first air duct. The plurality of evaporators are separately connected in series into a plurality of refrigeration circuits independent of each other, and each of the plurality of refrigeration circuits is configured for flow of a cooling medium.

### CROSS REFERENCE TO RELATED APPLICATION

This application claims priority to Chinese Patent Application No. 202310980109.5, titled “REFRIGERATION DEVICE AND DATA CENTER” and filed to the China National Intellectual Property Administration on August 4, the entire contents of which are incorporated herein by reference.

### TECHNICAL FIELD

Embodiments of the present disclosure relate to the field of refrigeration technology, and more particularly, to a refrigeration device and a data center.

### BACKGROUND

With the development of intelligent technologies, processing capacity of digital information is rapidly increasing. In the face of rapidly growing business demands and users' huge expectations to data processing and information exchange, generally number of IT devices in data centers is increased to meet the users' requirements for information network systems in terms of technical performance, data processing capacity, storage capacity, and utilization rate, etc. However, this may lead to increase in heat density of the data centers.

In related technologies, indirect evaporative cooling is generally selected to dissipate heat from the data center. Principles of the indirect evaporative cooling are as below. Cooling capacity of outdoor cold air is utilized, in combination with principles of water evaporative cooling, to transfer heat from hot air in computer rooms of the data centers to the outdoor cold air by means of non-direct contact heat exchangers, thereby cooling the hotter air in the computer rooms of the data centers. That is, cooling is obtained from natural environment, and the computer rooms of the data centers are cooled by means of the outdoor cold air.

However, the manner of the indirect evaporative cooling has the disadvantage of poorer accuracy in temperature control.

### SUMMARY

Objectives of embodiments of the present disclosure are to provide a refrigeration device and a data center, which can solve the problem of poorer accuracy in temperature control.

To achieve the above objectives, one aspect of the embodiments of the present disclosure provides a refrigeration device for a computer room. The refrigeration device includes a plurality of evaporators and a mixer. The plurality of evaporators are arranged in a first air duct forming an air circuit with an inner cavity of the computer room, where the air circuit is configured for flow of air. The plurality of evaporators are arranged at intervals in an array, and a connecting line between any two of the plurality of evaporators intersects in a direction of flow of the air in the first air duct. The plurality of evaporators are separately connected in series into a plurality of refrigeration circuits independent of each other, and each of the plurality of refrigeration circuits is configured for flow of a cooling medium. The mixer is arranged in the first air duct and is positioned downstream of the plurality of evaporators. The mixer is configured to mix air from the different evaporators and blow the air having a uniform temperature to the downstream.

Alternatively, the refrigeration device also includes an air-to-air heat exchanger, which has a first pipeline and a second pipeline for mutual heat exchange, where the first pipeline is connected in series in the air circuit, and an air inlet end and an air outlet end of the second pipeline are both communicated with outside.

Alternatively, the first air duct includes a first part and a second part, where the first part is connected in series with the first pipeline, the second part is connected in parallel with the first pipeline, and the mixer and the plurality of evaporators are arranged in the first part. The air circuit is provided with a valve, which has a first position for opening the first pipeline and closing the second part and a second position for closing the first pipeline and opening the second part.

Alternatively, the refrigeration device also includes a plurality of condensers and a plurality of compressors, where the plurality of condensers, the plurality of compressors, and the plurality of evaporators are communicated end to end in one-to-one correspondence to form the plurality of refrigeration circuits independent of each other.

Alternatively, the plurality of evaporators are arranged between the first pipeline and the mixer; and/or the plurality of condensers are arranged at intervals in a second air duct, where the second air duct is communicated with the second pipeline, and the plurality of condensers are positioned downstream of the second pipeline.

Alternatively, the air-to-air heat exchanger has a first surface and a second surface adjacent to each other, where the first surface intersects with an axis of the first air duct, the second surface intersects with an axis of the second air duct, and the first surface intersects with the second surface to form an intersecting line. The plurality of evaporators are arranged on one side of the first surface of the air-to-air heat exchanger, and the plurality of evaporators are arranged at intervals along a direction parallel to the first surface, and the plurality of evaporators are arranged in ascending order as they gradually stay away from the intersecting line. The plurality of condensers are arranged on one side of the second surface of the air-to-air heat exchanger, and the plurality of condensers are arranged at intervals along a direction parallel to the second surface, and the plurality of condensers are arranged in ascending order as they gradually stay away from the intersecting line. Number of the plurality of evaporators is equal to number of the plurality of condensers, and the evaporator and the condenser having a same serial number form the same refrigeration circuit.

Alternatively, the mixer includes an air guide element arranged in the first air duct, where the air guide element is configured to change a direction of movement of the air from the different evaporators and cause the air from the different evaporators to collide and mix; and/or the mixer includes a stirrer, which is rotatably arranged in the first air duct to mix the air from the different evaporators.

Alternatively, the refrigeration device also includes a first fan, where the first fan is arranged in the first air duct and is configured to guide the air in the first air duct, and the first fan is positioned between the plurality of evaporators and the mixer. The refrigeration device also includes a second fan, which is arranged in the second air duct and is configured to guide the air in the second air duct.

Alternatively, the refrigeration device also includes a spray apparatus, which is configured to spray a cooling medium into the air-to-air heat exchanger when the spray apparatus is turned on.

Alternatively, the refrigeration device has a first overall gear, a second overall gear, and a third overall gear. When the refrigeration device is in the first overall gear, the first fan and the second fan are turned on, the spray apparatus is turned off, and all the plurality of refrigeration circuits are closed. When the refrigeration device is in the second overall gear, the first fan and the second fan are turned on, the spray apparatus is turned on, and all the plurality of refrigeration circuits are closed. When the refrigeration device is in the third overall gear, the first fan and the second fan are turned on, the spray apparatus is turned on, and at least one of the plurality of refrigeration circuits is turned on. The third overall gear has a plurality of sub gears, and in each of the plurality of sub gears, numbers of the refrigeration circuits turned on are different.

To achieve the above objectives, another aspect of the embodiments of the present disclosure also provides a data center, which includes a computer room and the refrigeration device as described above.

In the refrigeration device and the data center provided in the embodiments of the present disclosure, a plurality of array evaporators are arranged in the first air duct forming the air circuit with the computer room, and a connecting line between any two of the plurality of evaporators intersects in the direction of flow of the air in the first air duct. Each evaporator is arranged in one refrigeration circuit, and the number of the refrigeration circuits turned on varies according to the temperature of the computer room. In this way, by quantitatively changing the number of the evaporators participating in cooling, the refrigeration capacity and the temperature can be accurately adjusted to overcome the disadvantage of poorer accuracy in temperature control in the indirect evaporative cooling.

In addition, the first air duct is also provided with a mixer positioned downstream of the plurality of evaporators. The mixer can mix air from different evaporators and blow the air having a uniform temperature to the downstream, to uniformize the temperature of the air blown out from the evaporators participating in cooling and the temperature of the air blown out from the evaporators not participating in cooling, such that the air entering the computer room has a uniform temperature.

### BRIEF DESCRIPTION OF THE DRAWINGS

To describe the technical solutions of the embodiments of the present disclosure more clearly, the accompanying drawings required in the description of the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a data center according to an embodiment of the present disclosure;

FIG. 2 is a schematic diagram of a first type of refrigeration device according to an embodiment of the present disclosure;

FIG. 3 is a schematic diagram of an arrangement of a plurality of evaporators according to an embodiment of the present disclosure;

FIG. 4 is a schematic diagram of another arrangement of a plurality of evaporators according to an embodiment of the present disclosure;

FIG. 5 is a schematic diagram of still another arrangement of a plurality of evaporators according to an embodiment of the present disclosure;

FIG. 6 is a schematic diagram of one of refrigeration circuits shown in FIG. 2;

FIG. 7 is a schematic diagram of a mixer according to an embodiment of the present disclosure;

FIG. 8 is a schematic diagram of another mixer according to an embodiment of the present disclosure;

FIG. 9 is a schematic diagram of a second type of refrigeration device according to an embodiment of the present disclosure;

FIG. 10 is a schematic diagram of a spray apparatus of the refrigeration device shown in FIG. 9;

FIG. 11 is a schematic diagram of the refrigeration device shown in FIG. 9 in a first overall gear;

FIG. 12 is a schematic diagram of the refrigeration device shown in FIG. 9 in a second overall gear;

FIG. 13 is a schematic diagram of the refrigeration device shown in FIG. 9 in a first sub gear;

FIG. 14 is a schematic diagram of the refrigeration device shown in FIG. 9 in a second sub gear; and

FIG. 15 is a schematic diagram of the refrigeration device shown in FIG. 9 in a third sub gear.

Reference numerals in the accompanying drawings:

refrigeration device 1000; first air duct 110; second air duct 120; mechanical refrigeration apparatus 200; evaporator 210; compressor 220; condenser 230; mixer 300; shell 310; air guide element 330; stirrer 340; air-to-air heat exchanger 400; first fan 500; second fan 600; spray apparatus 700; spray nozzle 70; reservoir 720; water supply pipe 730; pump body 740; and computer room 2000.

### DETAILED DESCRIPTION

As described in the background, the indirect evaporative cooling method in related technologies has the disadvantage of poorer accuracy in temperature control. In response to the above-mentioned technical disadvantage, embodiments of the present disclosure provide a refrigeration device and a data center. By quantitatively changing number of evaporators participating in cooling, refrigeration capacity and temperature can be accurately adjusted to overcome the disadvantage of poorer accuracy in temperature control in the indirect evaporative cooling. In addition, considering that uneven positions of the evaporators participating in cooling may lead to uneven outlet air temperature of the refrigeration device, a mixer is arranged downstream of a plurality of evaporators, such that the outlet air temperature is uniform.

To make the objectives, technical solutions, and advantages of the embodiments of the present disclosure clearer, the technical solutions in the embodiments of the present disclosure will be described clearly and completely below, in conjunction with the accompanying drawings in the embodiments of the present disclosure. Apparently, the described embodiments are some but not all of the embodiments of the present disclosure.

All other embodiments obtained by a person of ordinary skill in the art based on the embodiments of the present disclosure without creative efforts shall fall within the protection scope of the present disclosure. The following embodiments and features thereof may be combined with each other on a non-conflict basis.

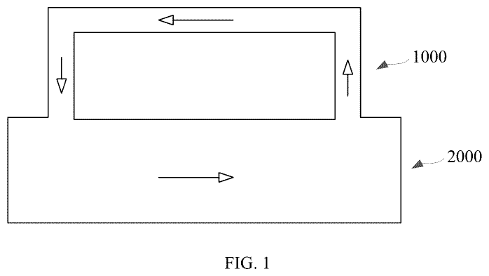

FIG. 1 is a schematic structural diagram of a data center according to an embodiment of the present disclosure. Referring to FIG. 1, the data center provided in the embodiments of the present disclosure may include a computer room 2000 and a refrigeration device 1000. The computer room 2000 may have an inner cavity. In the inner cavity of the computer room 2000 there may be provided with a computing device such as a server. The inner cavity of the computer room 2000 may be communicated with a first air duct 110 to form an air circuit, which may be configured for flow of air. As an example, the refrigeration device 1000 may include a shell 310 or pipe body, where the shell 310 or pipe body may have a first air duct 110. Alternatively, the first air duct 110 is formed by a pipe body other than the refrigeration device 1000 or shells 310 of other apparatuses. Alternatively, some first air ducts 110 may be formed by the refrigeration device 1000, and some first air ducts 110 may be formed by other pipe bodies or the shells 310 of other apparatuses.

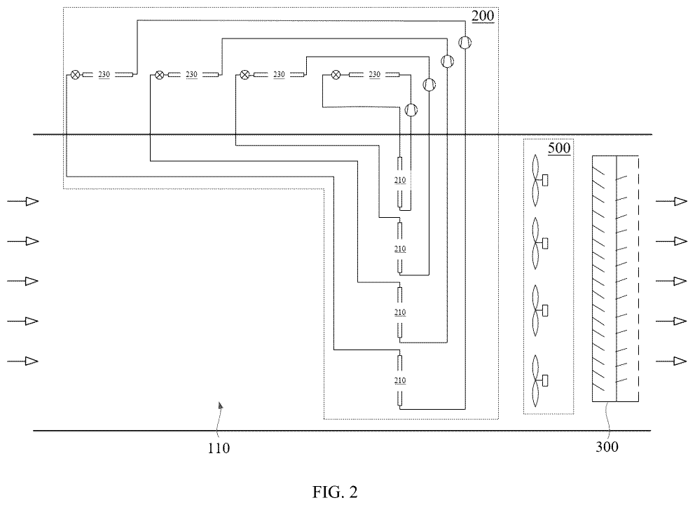

Hollow arrows in FIG. 1 represent directions of flow of air. Referring to FIG. 1, as an example, the computer room 2000 may have an air inlet and an air outlet, and the air inlet may be communicated with the air outlet through the inner cavity of the computer room 2000. Two open ends of the first air duct 110 may be communicated with the air inlet and the air outlet of the computer room 2000, respectively. The air in the first air duct 110 may flow into the inner cavity of the computer room 2000 through the air inlet, and the air in the inner cavity of the computer room 2000 may flow into the first air duct 110 through the air outlet. In this way, the first air duct 110 forms an annular air circuit together with the inner cavity of the computer room 2000, and the air may circulate in the air circuit under the action of a first fan 500 (as shown in FIG. 2) mentioned below.

FIG. 2 is a schematic diagram of a first type of refrigeration device 1000 according to an embodiment of the present disclosure. Referring to FIG. 2, the refrigeration device 1000 provided in the embodiments of the present disclosure may include a mechanical refrigeration apparatus 200, which may include a plurality of evaporators 210, where the plurality of evaporators 210 may be arranged in an array in the first air duct 110. A connecting line between any two of the plurality of evaporators 210 intersects in the direction of flow of the air (the hollow arrow in FIG. 2 represents the direction of flow of the air) in the first air duct 110. That is, none of the connecting lines between any two evaporators 210 is parallel to the direction of flow of the air. The connecting line between the two evaporators 210 mentioned above refers to a connecting line such as a geometric center or gravity center between the two evaporators 210. Generally, the direction of flow of the air is an axis direction of the first air duct 110.

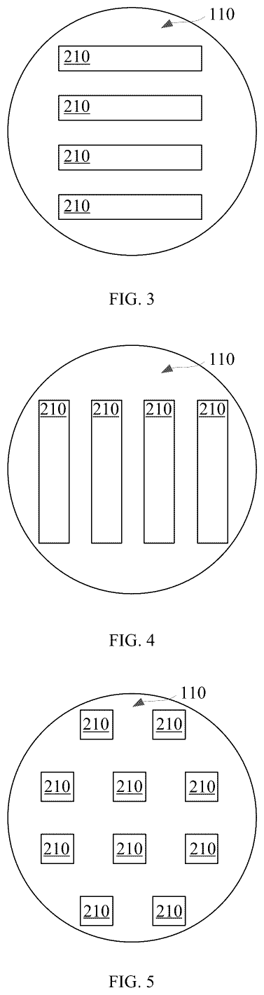

As an example, in FIG. 3, the direction of flow of the air is perpendicular to a paper surface, and the plurality of evaporators 210 are arranged at intervals along an above-below direction. In FIG. 4, the direction of flow of the air is perpendicular to the paper surface, and the plurality of evaporators 210 are arranged at intervals along a left-right direction. In FIG. 5, the direction of flow of the air is perpendicular to the paper surface, and the plurality of evaporators 210 are dispersed in a grid pattern. It is taken an example in FIGS. 3 to 5 where the connecting line between any two of the plurality of evaporators 210 is perpendicular to the direction of flow of the air. Of course, there may also exist cases where an angle between the connecting line between any two of the plurality of evaporators 210 and the direction of flow of the air is greater than 0 degree but is less than 90 degrees, which are not to be listed one by one here.

A first direction is perpendicular to the direction of flow of the air. To reduce a length of the first air duct 110 occupied by the plurality of evaporators 210, alternatively, these evaporators 210 have overlapped portions along the direction of flow of the air. That is, orthographic projections of these evaporators 210 on a projection plane along the first direction are at least partially overlapped. The projection plane is an imaginary plane perpendicular to the first direction. As an example, in FIG. 3, the first direction is the above-below direction, and the orthogonal projections of the plurality of evaporators 210 along the above-below direction are overlapped. In FIG. 4, the first direction is the left-right direction, and the orthogonal projections of the plurality of evaporators 210 along the left-right directions are overlapped. In FIG. 5, the first direction may be the above-below direction or the left-right direction. Further, end faces of these evaporators 210 along the direction of flow of the air are aligned.

In addition, to ensure that the plurality of evaporators 210 can achieve maximum cooling effects, alternatively, cross-sections of these evaporators 210 at a certain position may cover a cross-section of the first air duct 110 at this position.

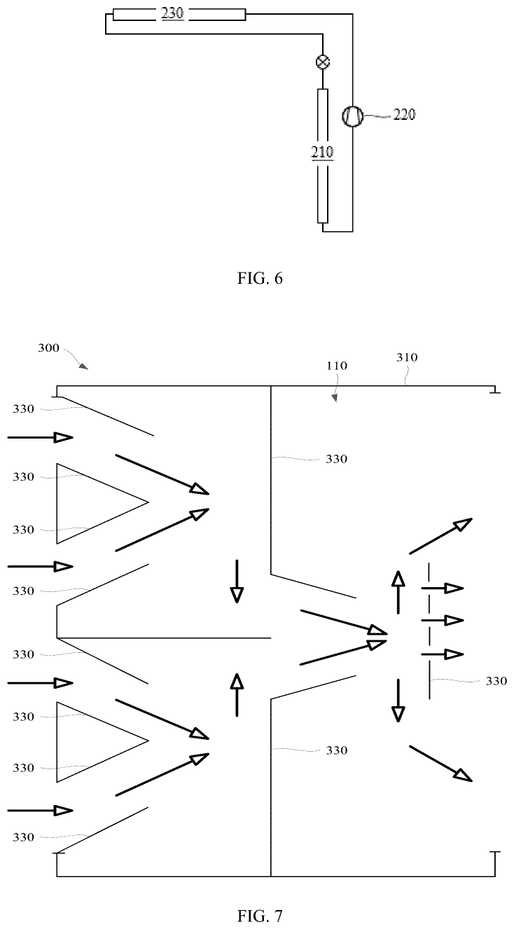

It should be noted that each of the evaporators 210 has an inner channel, which can exchange heat with the air passing through evaporator 210 when the low-temperature liquid heat transfer medium flows through the inner channel, to reduce the temperature of the air. When the low-temperature liquid heat transfer medium continuously flows through the inner channel, the evaporators 210 can continuously cool the air passing through the evaporators 210. To obtain the low-temperature liquid heat transfer medium continuously, the evaporators 210 may be connected in series into refrigeration circuits. FIG. 6 is a schematic diagram of one of the refrigeration circuits shown in FIG. 2. Referring to FIG. 6, each of the refrigeration circuits may be formed by components such as the evaporator 210, a compressor 220, and a condenser 230, and each of the refrigeration circuits may be provided with a power apparatus such as a water pump, such that a cooling medium may circulate in the refrigeration circuit.

Referring to FIG. 2, the plurality of evaporators 210 may be separately connected in series into a plurality of refrigeration circuits independent of each other. Specifically, a plurality of condensers 230, the plurality of compressors 220, and the plurality of evaporators 210 may be communicated end to end in one-to-one correspondence to form the plurality of refrigeration circuits independent of each other. As an example, FIG. 2 shows four refrigeration circuits. In each of the four refrigeration circuits, the evaporator 210, the compressor 220, and the condenser 230 may be communicated end to end through pipelines. Each of the refrigeration circuits may be provided with the water pump, such that the heat transfer medium may circulate in the refrigeration circuit.

The refrigeration circuit may have two states, i.e. an open state and a closed state. When the refrigeration circuit is in the open state, the power apparatus on the refrigeration circuit is turned on, such that the heat transfer medium circulates in the refrigeration circuit, and thus the evaporator 210 may cool the air passing through it. That is, the evaporator 210 participates in cooling. When the refrigeration circuit is in the closed state, the power apparatus on the refrigeration circuit is turned off, such that the heat transfer medium is in a static state. In this case, the inner channel of the evaporator 210 cannot continuously flow through the low-temperature liquid heat transfer medium, and thus the evaporator 210 cannot continuously cool the air passing through it. That is, the evaporator 210 does not participate in cooling.

It is to be understood that the more evaporators 210 participate in cooling, the greater the cooling capacity of the refrigeration device 1000 is, and the faster the air is cooled, but the higher consumption of energy such as electric energy is. Otherwise, the fewer evaporators 210 participate in cooling, the smaller the cooling capacity of the refrigeration device 1000 is, and the slower the air is cooled, but the lower consumption of the energy such as the electric energy is. In addition, when the refrigeration circuit is started, the condenser 230 needs to dissipate heat to outside (an outer side of the air circuit). When external heat is higher, the number of the evaporators 210 participating in cooling may be increased.

In view of this, the refrigeration device 1000 provided in the embodiments of the present disclosure may also include a controller in communication connection with the power apparatus such as the water pump. The controller can control an appropriate number of evaporators 210 to participate in cooling according to information such as temperature of the current computer room 2000, temperature of the target computer room 2000, external temperature, and energy consumption, etc. In this way, by quantitatively changing the number of the evaporators 210 participating in cooling, the refrigeration capacity and the temperature can be accurately adjusted to overcome the disadvantage of poorer accuracy in temperature control in the indirect evaporative cooling.

To ensure uniform temperature of the air blown out, referring to FIG. 2, the refrigeration device 1000 provided in the embodiments of the present disclosure may also include a mixer 300. The mixer 300 may be arranged in the first air duct 110 and positioned downstream of the plurality of evaporators 210. The mixer 300 is configured to mix the air from the different evaporators 210 and blow the air having uniform temperature to the downstream. In this way, the mixer 300 can uniformize the temperature of the air blown out from the evaporators 210 participating in cooling and the temperature of the air blown out from the evaporators 210 not participating in cooling, such that the air entering the computer room 2000 has the uniform temperature.

The mixer 300 may have following possible implementations.

In one possible implementation of the mixer 300, referring to FIG. 7, the mixer 300 may include an air guide element 330, which may be arranged in the first air duct 110. The air guide element 330 can change a direction of movement of the air from the different evaporators 210, and can cause the air from the different evaporators 210 to collide and mix, to achieve the objective of uniform mixing.

Specifically, initially the air from the different evaporators 210 moves along flow paths parallel to each other. After the air encounters the air guide element 330, the air guide element 330 can change flow directions of at least two groups of air (from the different evaporators 210), and allow the flow directions of the at least two groups of air to intersect, such that the at least two groups of air collide and exchange heat with each other, to uniformize the temperature of the air.

As an example, the hollow arrows in FIG. 1 represent the directions of flow of the air. Initially, there are four groups of initial air parallel to each other. After passing through the air guide element 330 on the left, two groups of initial air positioned above collide and exchange heat with each other to form one group of primary heat exchange air, while two groups of initial air positioned below collide and exchange heat with each other to form one group of primary heat exchange air. After passing through the air guide element 330 in the middle, the two groups of primary heat exchange air collide and exchange heat with each other to form one group of secondary heat exchange air. After passing through the air guide element 330 on the right, one group of more concentrated secondary heat exchange air is dispersed in all directions. It should be noted that FIG. 7 only serves as an example and does not provide specific limitations. Of course, there may be other ways to arrange the air guide element 330, as long as the air guide element 330 can ensure that the air from the different evaporators 210 can collide, mix and exchange heat with each other.

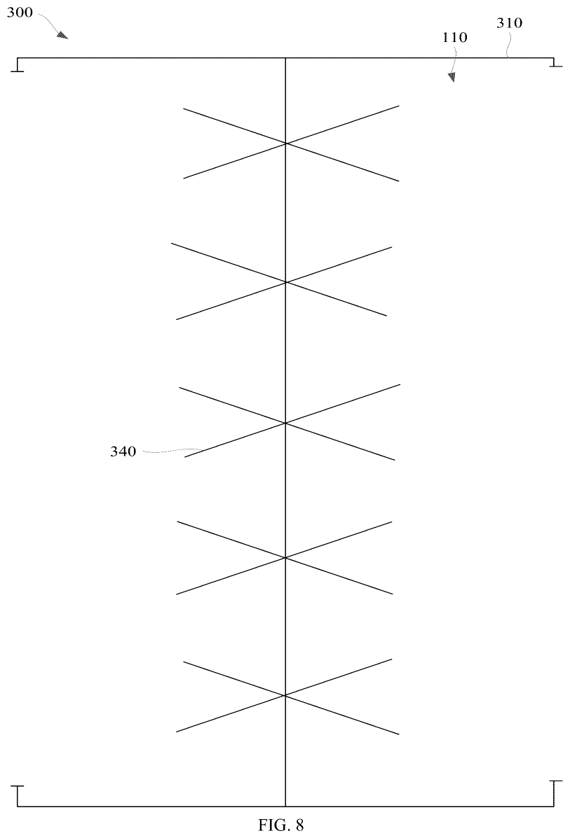

In another possible implementation of the mixer 300, referring to FIG. 8, the mixer 300 may include a stirrer 340, which may be rotatably arranged in the first air duct 110 to mix the air from the different evaporators 210. The stirrer 340 may be a component such as a fan blade that can mix and stir the air in the first air duct 110. In addition, to improve mixing efficiency, additionally, a rotation axis of the stirrer 340 may be perpendicular to the axis direction of the first air duct 110. Alternatively, there may be a plurality of stirrers 340, and the rotation axes of the plurality of stirrers 340 may intersect with each other.

In still another possible implementation of the mixer 300, the above two implementations of the mixer 300 may be combined with each other.

To improve mixing effects, alternatively, the first fan 500 may be arranged in the first air duct 110, and the first fan 500 can guide the air in the first air duct 110. The first fan 500 may be positioned between the plurality of evaporators 210 and the mixer 300.

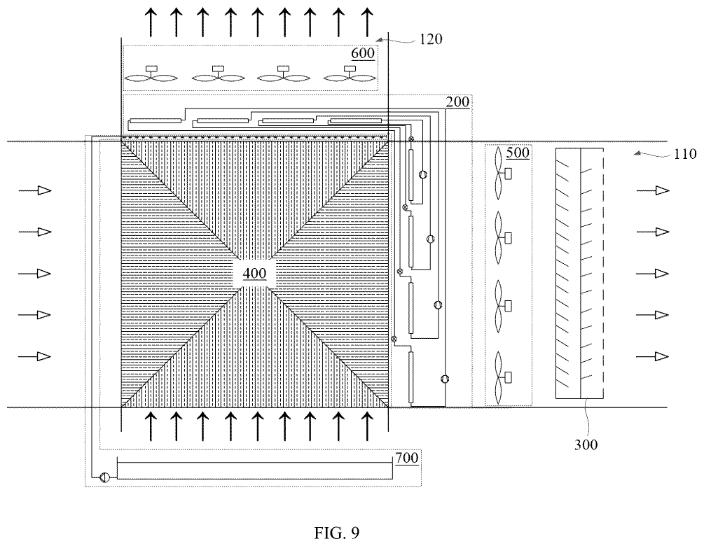

FIG. 9 is a schematic diagram of a second type of refrigeration device 1000 according to an embodiment of the present disclosure. Referring to FIG. 9, the refrigeration device 1000 provided in the embodiments of the present disclosure may also include an air-to-air heat exchanger 400, which may have a first pipeline and a second pipeline for mutual heat exchange. The first pipeline may be connected in series in the air circuit, such that the computer room 2000, the first pipeline, and at least part of the first air duct 110 may form the air circuit. Two open ends of the second pipeline may be both communicated with the outside. In this way, fresh air from the outside (such as outside the computer room 2000) may be guided by a second fan 600 to enter the second pipeline from an air inlet end of the second pipeline, and may exchange heat with the air participating in the air circuit in the first pipeline, and flow out from an air outlet end of the first pipeline to the outside.

Alternatively, the first pipeline may be arranged upstream of the plurality of evaporators 210. That is, the plurality of evaporators 210 may be arranged between the first pipeline and the mixer 300. The first air duct 110 may include a first part and a second part, where the first part may be connected in series with the first pipeline, the second part may be connected in parallel with the first pipeline, and the mixer 300 and the plurality of evaporators 210 are arranged in the first part. A valve may be arranged near the air inlet end of the first pipeline, and the valve may have a first position for opening the first pipeline and closing the second part and a second position for closing the first pipeline and opening the second part.

When the temperature of the fresh air outside is lower than that of the computer room 2000, the valve may be placed in the first position, such that the air flowing out of the computer room 2000 may first enter the first pipeline and may be cooled by the fresh air outside, and then enter the first part of the first air duct 110, and the cooled air may be selectively cooled by the heat transfer medium in the evaporator 210. When the temperature of the fresh air outside is slightly different from that of the computer room 2000, or when the temperature of the fresh air outside is higher than that of the computer room 2000, the valve may be placed in the second position, such that the air flowing out of the computer room 2000 may first enter the second part of the first air duct 110, and then enter the first part of the first air duct 110 and is cooled by the heat transfer medium in the evaporator 210.

Alternatively, a second air duct 120 may be communicated with the second pipeline. That is, the second pipeline is connected in series to the second air duct 120. The plurality of condensers 230 may be arranged at intervals in the second air duct 120, and the plurality of condensers 230 may be positioned downstream of the second pipeline. That is, the fresh air from the outside may pass through the second pipeline and the plurality of condensers 230 in sequence under the guidance of the second fan 600, such that the fresh air from the outside may exchange heat with the air in the first pipeline and the condenser 230. The second fan 600 may be arranged in the second air duct 120. Alternatively, the plurality of condensers 230 may be arranged in the second air duct 120 at intervals in an array, and a connecting line between any two of the plurality of condensers 230 may intersect in a direction of flow of the air in the second air duct 120.

It is to be noted that the refrigeration device 1000 may include a shell 310 or pipe body, where the shell 310 or pipe body may have the second air duct 120. Alternatively, the second air duct 120 is formed by a pipe body other than the refrigeration device 1000 or shells 310 of other apparatuses. Alternatively, some second air ducts 120 may be formed by the refrigeration device 1000, and some second air ducts 120 may be formed by other pipe bodies or the shells 310 of other apparatuses.

For the convenience of arrangement of pipelines in the refrigeration circuit, alternatively, the air-to-air heat exchanger 400 may have a first surface and a second surface adjacent to each other, where the first surface may intersect with an axis of the first air duct 110, the second surface may intersect with an axis of the second air duct 120, and the first surface intersects with the second surface to form an intersecting line.

The plurality of evaporators 210 may arranged on one side of the first surface of the air-to-air heat exchanger 400, and the plurality of evaporators 210 may be arranged at intervals along a direction parallel to the first surface, and the plurality of evaporators 210 may be arranged in ascending order as they gradually stay away from the intersecting line; The plurality of condensers 230 may be arranged on one side of the second surface of the air-to-air heat exchanger 400, and the plurality of condensers 230 may be arranged at intervals along a direction parallel to the second surface, and the plurality of condensers 230 may be arranged in ascending order as they gradually stay away from the intersecting line. Number of the plurality of evaporators 210 is equal to number of the plurality of condensers 230, and the evaporator 210 and the condenser 230 having a same serial number form the same refrigeration circuit.

With continued reference to FIG. 9, the refrigeration device 1000 provided in the embodiments of the present disclosure may also include a spray apparatus 700, which may spray a cooling medium such as low-temperature water into the air-to-air heat exchanger 400 when the spray apparatus 700 is turned on, to reduce the temperature of the air in the second pipeline and the temperature of the air in the first pipeline.

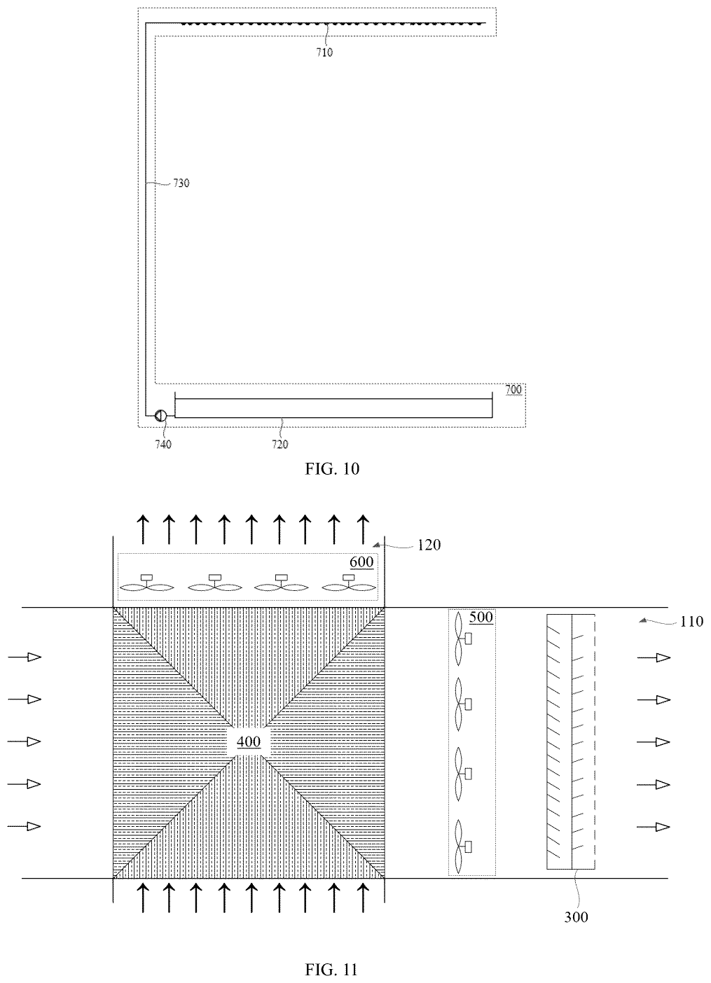

Referring to FIG. 9 and FIG. 10, specifically, the spray apparatus 700 may include a spray nozzle 70, a pump body 740, a reservoir 720, and a water supply pipe 730. When the spray apparatus 700 is turned on, the pump body 740 may be started, and the pump body 740 can transport the cooling medium stored in the reservoir 720 to the spray nozzle 70 through the water supply pipe 730, and the spray nozzle 70 sprays the cooling medium to the air-to-air heat exchanger 400. When the spray apparatus 700 is turned off, the pump body 740 may be turned off, and the spray nozzle 70 no longer sprays the cooling medium into the air-to-air heat exchanger 400. Alternatively, the spray nozzle 70 may be arranged above the air-to-air heat exchanger 400, and the reservoir 720 may be arranged below the air-to-air heat exchanger 400, such that unevaporated liquid drops obtained after exchanging heat with the second pipeline can flow back into the reservoir 720 due to gravity.

Alternatively, the refrigeration device 1000 provided in the embodiments of the present disclosure may have a first overall gear, a second overall gear, and a third overall gear.

Referring to FIG. 11, when the refrigeration device 1000 is in the first overall gear, both the first fan 500 and the second fan 600 may be turned on, the spray apparatus 700 may be turned off, and all the plurality of refrigeration circuits may be closed. In this way, the computer room 2000 is cooled by the fresh air from the outside through the air-to-air heat exchanger 400.

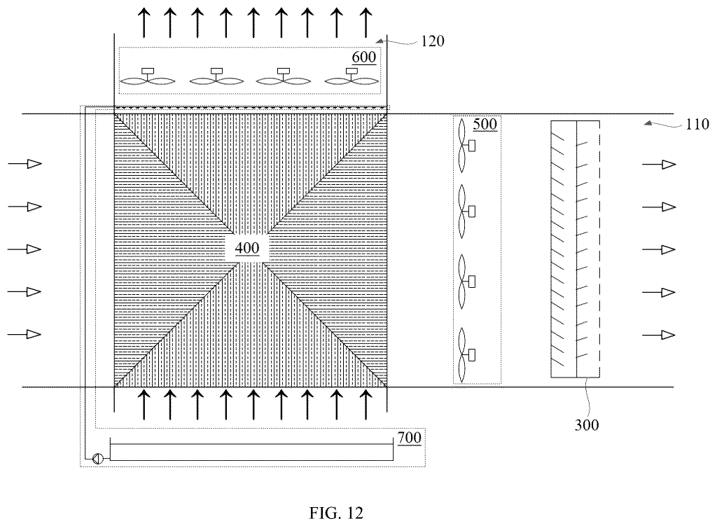

Referring to FIG. 12, when the refrigeration device 1000 is in the second overall gear, both the first fan 500 and the second fan 600 may be turned on, the spray apparatus 700 may be turned on, and all the plurality of refrigeration circuits may be closed. In this way, on the basis of cooling the computer room 2000 by the fresh air from the outside through the air-to-air heat exchanger 400, additionally the computer room 2000 is cooled by the cooling medium sprayed out from the spray apparatus 700, to improve the cooling effects.

Referring to FIG. 9 and FIGS. 13 to 15, when the refrigeration device 1000 is in the third overall gear, both the first fan 500 and the second fan 600 may be turned on, the spray apparatus 700 may be turned on, and at least one of the plurality of refrigeration circuits may be turned on. In this way, on the basis of the above two gears, the evaporator 210 is further provided to cool down the computer room 2000, to further improve the cooling effects.

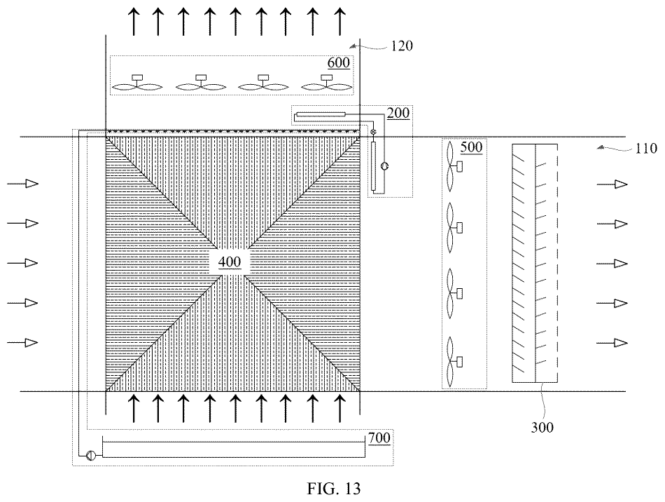

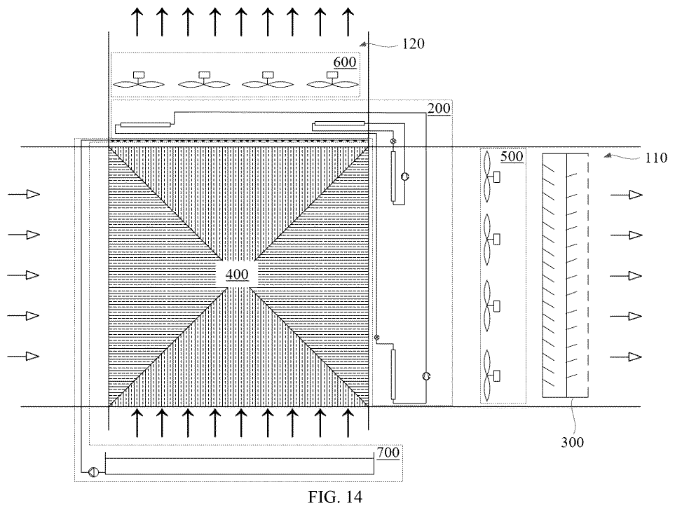

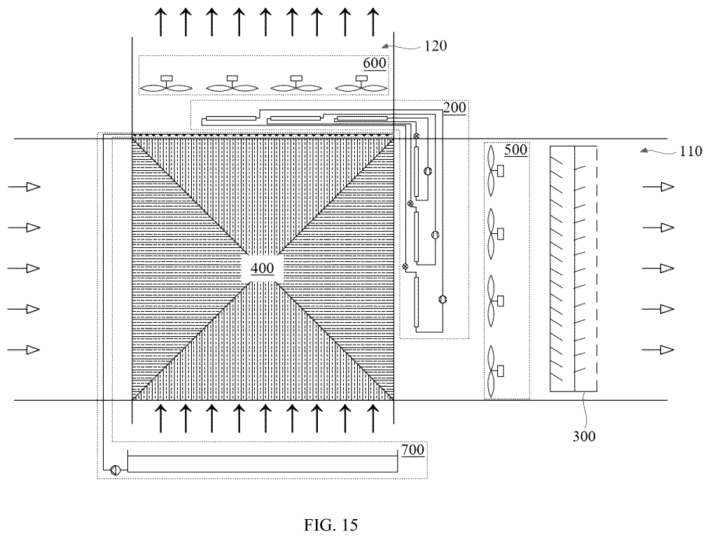

The third overall gear may have a plurality of sub gears, and in each of the plurality of sub gears, numbers of the refrigeration circuits turned on are different. As an example, in FIG. 13, one refrigeration circuit is turned on; in FIG. 14, two refrigeration circuits are turned on; in FIG. 15, three refrigeration circuits are turned on; and in FIG. 9, four refrigeration circuits are turned on.

In summary, the refrigeration device provided in the embodiments of the present disclosure solves problems that utilization of natural cooling sources is lower, temperature of a data center computer room cannot be reasonably regulated and controlled, spray cooling of traditional evaporative cooling units does not match load of a cooling side, water consumption is excessive, mechanical refrigeration input timing is not reasonable, operation time is longer, and energy consumption is higher. In addition, the refrigeration device provided in the embodiments of the present disclosure can achieve precise regulation of the temperature of the data center computer room. During a whole year operation period, through precise regulation and control, based on seasonal and diurnal temperature variations, natural cold sources are utilized to accurately regulate the temperature of the data center computer room, thereby reducing time and load of mechanical refrigeration operation, and meeting the precise regulation of mechanical refrigeration. Cold air conveyed into the computer room is mixed, to meet the requirement for uniformity of supply air temperature. Energy consumption for air conditioning in the data center is reduced, and consumption of water resources is reduced.

The terms such as “upper” and “lower” used to describe relative positional relationships of various structures in the drawings are merely for the purpose of concise description rather than limiting the implementable scope of the present disclosure. The changes or adjustments of the relative relationship without a substantial modification to the technical solutions are regarded as being covered by the implementable scope of the present disclosure.

It is to be noted that in the present disclosure, unless specified or limited otherwise, a first feature “on” or “below” a second feature may include an embodiment in which the first feature is in direct contact with the second feature, and may also include an embodiment in which the first feature and the second feature are in indirect contact via an intermediary. Furthermore, a first feature “on,” “above,” or “on top of” a second feature may include an embodiment in which the first feature is right or obliquely “on,” “above,” or “on top of” the second feature, or just means that the first feature is at a height higher than that of the second feature. A first feature “below,” “under,” or “on bottom of” a second feature may include an embodiment in which the first feature is right or obliquely “below,” “under,” or “on bottom of” the second feature, or just means that the first feature is at a height lower than that of the second feature.

In addition, in the present disclosure, unless specified or limited otherwise, terms “mounted”, “connected”, “coupled”, “fixed” and so on should be understood in a broad sense, which may be, for example, a fixed connection, a detachable connection or integrated connection, a direct connection or indirect connection by means of an intermediary, an internal communication between two elements or an interaction relationship between two elements. The specific significations of the above terms in the present disclosure may be understood in the light of specific conditions by persons of ordinary skill in the art.

Reference throughout this specification to the terms “an embodiment,” “some embodiments,” “an exemplary embodiment,” “an example,” “a specific example,” or “some examples,” means that a specific feature, structure, material, or characteristic described in connection with the embodiment or example is included in at least one embodiment or example of the present disclosure. The schematic representation of the above terms throughout this specification are not necessarily referring to the same embodiment or example. Furthermore, the specific features, structures, materials, or characteristics set forth may be combined in any suitable manner in one or more embodiments or examples.

Finally, it should be noted that the foregoing embodiments are merely intended for describing the technical solutions of the present disclosure, but not for limiting the present disclosure. Although the present disclosure is described in detail with reference to the foregoing embodiments, persons of ordinary skill in the art should understand that they may still make modifications to the technical solutions described in the foregoing embodiments or make equivalent replacements to some or all technical features thereof, which does not make corresponding technical solutions in essence depart from the scope of the technical solutions of the embodiments of the present disclosure.

What is claimed is:

1. A refrigeration device for a computer room, the refrigeration device comprising:
a plurality of evaporators arranged in a first air duct forming an air circuit with an inner cavity of the computer room, the air circuit being configured for flow of air; wherein the plurality of evaporators are arranged at intervals in an array, and a connecting line between any two of the plurality of evaporators intersects in a direction of flow of the air in the first air duct; the plurality of evaporators are separately connected in series into a plurality of refrigeration circuits independent of each other, each of the plurality of refrigeration circuits being configured for flow of a cooling medium; and
a mixer arranged in the first air duct and positioned downstream of the plurality of evaporators, the mixer being configured to mix air from the different evaporators and blow the air having a uniform temperature to the downstream.

2. The refrigeration device according to claim 1, further comprising an air-to-air heat exchanger, wherein the air-to-air heat exchanger has a first pipeline and a second pipeline for mutual heat exchange, the first pipeline is configured to be connected in series in the air circuit, and an air inlet end and an air outlet end of the second pipeline are both communicated with outside.

3. The refrigeration device according to claim 2, wherein the first air duct comprises a first part and a second part, the first part is connected in series with the first pipeline, the second part is connected in parallel with the first pipeline, and the mixer and the plurality of evaporators are arranged in the first part; and
the air circuit is provided with a valve having a first position for opening the first pipeline and closing the second part and a second position for closing the first pipeline and opening the second part.

4. The refrigeration device according to claim 2, further comprising a plurality of condensers and a plurality of compressors, wherein the plurality of condensers, the plurality of compressors, and the plurality of evaporators are communicated end to end in one-to-one correspondence to form the plurality of refrigeration circuits independent of each other.

5. The refrigeration device according to claim 4, wherein the plurality of evaporators are arranged between the first pipeline and the mixer; and/or
the plurality of condensers are configured to be arranged at intervals in a second air duct, the second air duct is communicated with the second pipeline, and the plurality of condensers are positioned downstream of the second pipeline.

6. The refrigeration device according to claim 5, wherein the air-to-air heat exchanger has a first surface and a second surface adjacent to each other, the first surface intersects with an axis of the first air duct, the second surface intersects with an axis of the second air duct, and the first surface intersects with the second surface to form an intersecting line;
the plurality of evaporators are arranged on one side of the first surface of the air-to-air heat exchanger, and the plurality of evaporators are arranged at intervals along a direction parallel to the first surface, and the plurality of evaporators are arranged in ascending order as the plurality of evaporators gradually stay away from the intersecting line;
the plurality of condensers are arranged on one side of the second surface of the air-to-air heat exchanger, and the plurality of condensers are arranged at intervals along a direction parallel to the second surface, and the plurality of condensers are arranged in ascending order as the plurality of condensers gradually stay away from the intersecting line; and
number of the plurality of evaporators is equal to number of the plurality of condensers, and the evaporator and the condenser having a same serial number form the same refrigeration circuit.

7. The refrigeration device according to claim 6, wherein the mixer comprises an air guide element arranged in the first air duct, and the air guide element is configured to change a direction of movement of the air from the different evaporators and cause the air from the different evaporators to collide and mix; and/or
the mixer comprises a stirrer rotatably arranged in the first air duct to mix the air from the different evaporators.

8. The refrigeration device according to claim 6, further comprising a first fan, wherein the first fan is arranged in the first air duct and is configured to guide the air in the first air duct, and the first fan is positioned between the plurality of evaporators and the mixer; and
the refrigeration device further comprises a second fan, and the second fan is arranged in the second air duct and is configured to guide the air in the second air duct.

9. The refrigeration device according to claim 8, further comprising a spray apparatus,
wherein the spray apparatus is configured to spray a cooling medium into the air-to-air heat exchanger when the spray apparatus is turned on.

10. The refrigeration device according to claim 9, wherein the refrigeration device has a first overall gear, a second overall gear, and a third overall gear;
when the refrigeration device is in the first overall gear, the first fan and the second fan are turned on, the spray apparatus is turned off, and all the plurality of refrigeration circuits are closed;
when the refrigeration device is in the second overall gear, the first fan and the second fan are turned on, the spray apparatus is turned on, and all the plurality of refrigeration circuits are closed;
when the refrigeration device is in the third overall gear, the first fan and the second fan are turned on, the spray apparatus is turned on, and at least one of the plurality of refrigeration circuits is turned on; and
the third overall gear has a plurality of sub gears, and in each of the plurality of sub gears, numbers of the refrigeration circuits turned on are different.

11. A data center, comprising a computer room and a refrigeration device, the refrigeration device comprising:
a plurality of evaporators arranged in a first air duct forming an air circuit with an inner cavity of the computer room, the air circuit being configured for flow of air; wherein the plurality of evaporators are arranged at intervals in an array, and a connecting line between any two of the plurality of evaporators intersects in a direction of flow of the air in the first air duct; the plurality of evaporators are separately connected in series into a plurality of refrigeration circuits independent of each other, each of the plurality of refrigeration circuits being configured for flow of a cooling medium; and
a mixer arranged in the first air duct and positioned downstream of the plurality of evaporators, the mixer being configured to mix air from the different evaporators and blow the air having a uniform temperature to the downstream.

12. The data center according to claim 11, further comprising an air-to-air heat exchanger, wherein the air-to-air heat exchanger has a first pipeline and a second pipeline for mutual heat exchange, the first pipeline is configured to be connected in series in the air circuit, and an air inlet end and an air outlet end of the second pipeline are both communicated with outside.

13. The data center according to claim 12, wherein the first air duct comprises a first part and a second part, the first part is connected in series with the first pipeline, the second part is connected in parallel with the first pipeline, and the mixer and the plurality of evaporators are arranged in the first part; and
the air circuit is provided with a valve having a first position for opening the first pipeline and closing the second part and a second position for closing the first pipeline and opening the second part.

14. The data center according to claim 12, further comprising a plurality of condensers and a plurality of compressors, wherein the plurality of condensers, the plurality of compressors, and the plurality of evaporators are communicated end to end in one-to-one correspondence to form the plurality of refrigeration circuits independent of each other.

15. The data center according to claim 14, wherein the plurality of evaporators are arranged between the first pipeline and the mixer; and/or
the plurality of condensers are configured to be arranged at intervals in a second air duct, the second air duct is communicated with the second pipeline, and the plurality of condensers are positioned downstream of the second pipeline.

16. The data center according to claim 15, wherein the air-to-air heat exchanger has a first surface and a second surface adjacent to each other, the first surface intersects with an axis of the first air duct, the second surface intersects with an axis of the second air duct, and the first surface intersects with the second surface to form an intersecting line;
the plurality of evaporators are arranged on one side of the first surface of the air-to-air heat exchanger, and the plurality of evaporators are arranged at intervals along a direction parallel to the first surface, and the plurality of evaporators are arranged in ascending order as the plurality of evaporators gradually stay away from the intersecting line;
the plurality of condensers are arranged on one side of the second surface of the air-to-air heat exchanger, and the plurality of condensers are arranged at intervals along a direction parallel to the second surface, and the plurality of condensers are arranged in ascending order as the plurality of condensers gradually stay away from the intersecting line; and
number of the plurality of evaporators is equal to number of the plurality of condensers, and the evaporator and the condenser having a same serial number form the same refrigeration circuit.

17. The data center according to claim 16, wherein the mixer comprises an air guide element arranged in the first air duct, and the air guide element is configured to change a direction of movement of the air from the different evaporators and cause the air from the different evaporators to collide and mix; and/or
the mixer comprises a stirrer rotatably arranged in the first air duct to mix the air from the different evaporators.

18. The data center according to claim 16, further comprising a first fan, wherein the first fan is arranged in the first air duct and is configured to guide the air in the first air duct, and the first fan is positioned between the plurality of evaporators and the mixer; and
the refrigeration device further comprises a second fan, and the second fan is arranged in the second air duct and is configured to guide the air in the second air duct.

19. The data center according to claim 18, further comprising a spray apparatus, wherein the spray apparatus is configured to spray a cooling medium into the air-to-air heat exchanger when the spray apparatus is turned on.

20. The data center according to claim 19, wherein the refrigeration device has a first overall gear, a second overall gear, and a third overall gear;
when the refrigeration device is in the first overall gear, the first fan and the second fan are turned on, the spray apparatus is turned off, and all the plurality of refrigeration circuits are closed;
when the refrigeration device is in the second overall gear, the first fan and the second fan are turned on, the spray apparatus is turned on, and all the plurality of refrigeration circuits are closed;
when the refrigeration device is in the third overall gear, the first fan and the second fan are turned on, the spray apparatus is turned on, and at least one of the plurality of refrigeration circuits is turned on; and
the third overall gear has a plurality of sub gears, and in each of the plurality of sub gears, numbers of the refrigeration circuits turned on are different.
